(19) United States
(12) Patent Application Publication
(10) Pub. No.: US 2025/0381768 A1
(43) Pub. Date: Dec. 18, 2025

(54) METHOD OF MANUFACTURING A DISPLAY DEVICE

(71) Applicant: SAMSUNG DISPLAY CO., LTD., YONGIN-SI (KR)

(72) Inventors: HEESUN AHN, Yongin-si (KR); DAEHYUN KIM, Yongin-si (KR); Seungjin SONG, Yongin-si (KR); Sangmi LEE, Yongin-si (KR); Seongwon LIM, Yongin-si (KR); KWANG JIN JEONG, Yongin-si (KR)

(21) Appl. No.: 19/087,710

(22) Filed: Mar. 24, 2025

(30) Foreign Application Priority Data
Jun. 17, 2024 (KR) 10-2024-0078146

(51) Int. Cl. B32B 37/02; B32B 7/06; B32B 7/12; B32B 17/10; B32B 27/36; B32B 37/12; B32B 38/00; H05K 5/03

(52) U.S. Cl. CPC B32B 37/02; B32B 7/06; B32B 7/12; B32B 17/10; B32B 27/36; B32B 37/12; B32B 38/0004; H05K 5/03; B32B 2457/20

(57) ABSTRACT

A method of manufacturing a display device including a three-dimensional display panel, includes attaching a guide film onto a back surface of the display panel, attaching an OCA film onto a front surface of the display panel, cutting the attached display panel, guide film, and OCA film, performing a pre-forming process by pressing the cut display panel, guide film, and OCA film onto a shape stage, performing a first bonding process by attaching and pressing a cover glass onto the OCA film, removing the shape stage from the guide film and introducing a diaphragm pad into a position where the shape stage was previously placed, performing a second bonding process by pressing the cover glass onto the diaphragm pad, and removing the diaphragm pad from the guide film and removing the guide film.

### CROSS-REFERENCE TO RELATED APPLICATION

This application claims priority under 35 U.S.C. § 119 to Korean Patent Application No. 10-2024-0078146, filed on Jun. 17, 2024 in the Korean Intellectual Property Office, the disclosure of which is incorporated by reference in its entirety herein.

### 1. TECHNICAL FIELD

The present disclosure relates to a method of manufacturing a display device.

### 2. DISCUSSION OF RELATED ART

A display device displays images using elements that emit light. Recently, flat panel displays have been widely used as display devices. Display devices include liquid crystal displays (LCDs), plasma display panels (PDPs), organic light emitting diode devices (OLEDs), field emission displays (FEDs), electrophoretic display devices, and the like, which have different light emitting methods from each other.

The display devices are generally manufactured in a flat shape and have rapidly replaced existing cathode ray tubes due to their increased performance in thinness, light weight, and low power consumption. Recently, flexible display panels capable of being bent have been developed. The flexible display panels may be bent or otherwise deformed for use in a folded or curved shape, for increased user convenience. The flexible display panels may be used in a variety of fields.

### SUMMARY

Embodiments of the present disclosure provide a method of manufacturing a display device capable of increasing reliability of the display device by minimizing defects occurring in the edge area of the three-dimensional display panel.

According to an embodiment of the present disclosure, a method of manufacturing a display device including a three-dimensional display panel, includes attaching a guide film onto a back surface of the display panel. An OCA film is attached onto a front surface of the display panel. The display panel, the guide film, and the OCA film that are attached to each other are cut. A pre-forming process is performed by pressing the cut display panel, guide film, and OCA film onto a shape stage with the guide film facing downward to form a shape of the cut display panel, guide film, and OCA film corresponding to an outer shape of the shape stage. A first bonding process is performed by attaching and pressing a cover glass onto the OCA film to form the cover glass into a shape corresponding to the outer shape of the shape stage. The shape stage is removed from the guide film and a diaphragm pad is introduced into a position where the shape stage was previously placed during the first bonding process. A second bonding process is performed by pressing the cover glass onto the diaphragm pad to form a shape of the cover glass corresponding to the outer shape of the diaphragm pad. The diaphragm pad is removed from the guide film and the guide film is removed.

In an embodiment, the OCA film may include a substrate and an OCA release liner attached to the substrate.

In an embodiment, the substrate may be a film that comprises polyethylene terephthalate (PET) or polyethylene naphthalate (PEN).

In an embodiment, the performing of the first bonding process may include peeling the OCA release liner from the substrate and bonding the cover glass onto the substrate.

In an embodiment, the guide film includes a plurality of grippers protruding to an outside of the display panel.

In an embodiment, the plurality of grippers may be symmetrically arranged around the display panel.

In an embodiment, the attached display panel, guide film, and OCA film may have a partially cut planar elliptical or circular shape.

In an embodiment, the cutting may include cutting the display panel, the guide film, and the OCA film that are attached to each other to have a central portion and an edge portion extending around the central portion.

In an embodiment, the central portion may be circular, and the edge portion may be partially paced apart from the central portion and partially connected to the central portion.

In an embodiment, the edge portion may be folded towards a back side of the display panel, forming a shape where the edge portion is connected to the central portion.

In an embodiment, the shape stage may correspond to a shape in which the edge portion is folded toward the back side of the display panel.

In an embodiment, a plurality of vacuum holes may be formed on an outer surface of the shape stage.

In an embodiment, the plurality of vacuum holes may be arranged to be uniformly distributed in the central portion and the edge portion.

In an embodiment, the plurality of vacuum holes may be through holes that allow the central portion and the edge portion to be adsorbed onto the outer surface of the shape stage by negative pressure generated on an inner surface of the shape stage.

In an embodiment, the method may further include after the removing of the guide film, attaching a protective layer to a position where the diaphragm pad was previously placed during the second bonding process.

In an embodiment, the protective layer may be a copper panel that dissipates heat and provides exterior protection of the display panel.

In an embodiment, the diaphragm pad may be composed of soft silicone.

In an embodiment, the performing the second bonding process may use a pressing force greater than a pressing force of the first bonding process.

According to an embodiment of the present disclosure, by manufacturing a display device that is completely bonded to a three-dimensional display panel, it is possible to prevent defects such as cracks, shrinkage, and bubbles from occurring in the edge area.

In addition, there is no need for complicated and diverse machine parts, such as clamps and rollers for the process, thereby reducing the possibility of malfunction and failure of equipment and increasing the productivity of the display panel window.

### BRIEF DESCRIPTION OF THE DRAWINGS

FIGS. 1 to 3 illustrate the process of forming a conventional display panel with rounded corners according to a comparative embodiment.

FIG. 4 is a diagram illustrating an electronic device with a display panel having rounded corners.

FIG. 5 illustrates a state in which a guide film is attached to a display panel in a method of manufacturing a display panel window according to an embodiment of the present disclosure.

FIG. 6 illustrates a state in which an OCA film is attached to a display panel in a method of manufacturing a display panel window according to an embodiment of the present disclosure.

FIG. 7 illustrates a cutting step in a method of manufacturing a display panel window according to an embodiment of the present disclosure.

FIG. 8 illustrates a pre-forming step in a method of manufacturing a display panel window according to an embodiment of the present disclosure.

FIG. 9 illustrates a state in which a diaphragm pad is introduced in a method of manufacturing a display panel window according to an embodiment of the present disclosure.

FIG. 10 is a flowchart showing a method of manufacturing a display panel window according to an embodiment of the present disclosure.

### DETAILED DESCRIPTION OF EMBODIMENTS

The present invention will be described more fully hereinafter with reference to the accompanying drawings, in which non-limiting embodiments of the present disclosure are shown. As those skilled in the art would realize, the described embodiments may be modified in various different ways, all without departing from the spirit or scope of the present disclosure.

To concisely describe embodiments of the present disclosure, parts that are irrelevant to the description may be omitted, and like reference numerals and/or reference characters refer to like or similar constituent elements throughout the specification.

Further, since sizes and thicknesses of constituent members shown in the accompanying drawings may be arbitrarily given to facilitate understanding and ease of description, embodiments of the present disclosure are not necessarily limited to the illustrated sizes and thicknesses. In the drawings, the thickness of layers, films, panels, regions, etc., may be exaggerated for clarity. In the drawings, to facilitate understanding and ease of description, the thicknesses of some layers and areas may be exaggerated.

It should be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean that it is positioned on the upper side of the object portion based on a gravitational direction.

In addition, unless explicitly stated to the contrary, the word “comprise,” and variations such as “comprises” or “comprising” should be understood to imply the inclusion of stated elements but not the exclusion of any other elements.

Embodiments of the present disclosure provide a method of manufacturing a three-dimensional display panel that includes attaching a guide film onto a back surface of the display panel and attaching an OCA film onto a front surface of the display panel. The attached display panel, guide film and OCA film are cut in a cutting process. A pre-forming process is then performed which presses the cut display panel, guide film and OCA film onto a shape stage. First and second bonding processes are then performed using the shape stage and a diaphragm pad, respectively.

In the manufacturing method, a display device is completely bonded to a three-dimensional display panel. Therefore, defects are prevented from occurring in the edge area. Additionally, the method obviates the need for complicated and diverse machine parts, such as clamps and rollers, providing an increase in manufacturing efficiency.

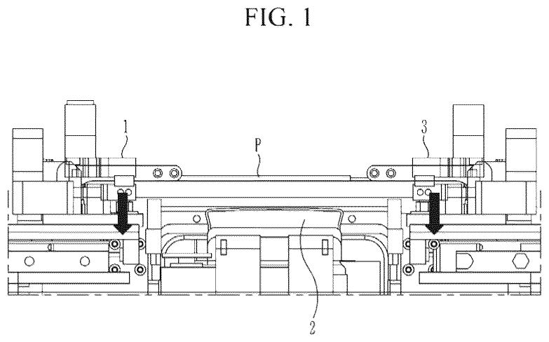

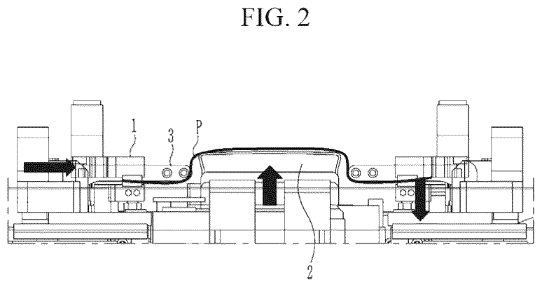

In some embodiments a display device may have rounded corners. To form a display device with rounded corners, a laminating process is performed to pressurize the display panel and window. As shown in FIGS. 1 to 3, in a comparative embodiment a flat display panel P (window attached) gripped by a clamp 1 on both sides is aligned on top of a shaping pad 2. As the clamp 1 is lowered by a clamp cylinder, the display panel P is also lowered, and the shaping pad 2 rises towards the back surface of the display panel P. At the same time, rollers 3 in direct contact with the upper surface of the display panel P on both sides of the display panel P advances towards the center of the display panel P, forming the display panel P that is bent towards the upper part (FIG. 2).

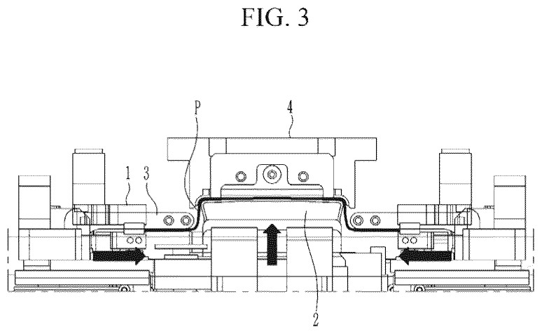

Subsequently, as shown in FIG. 3 an upper pressing jig 4 descends from the top of the display panel P and simultaneously presses the upper, lower, and side surfaces of the display panel P together with the shaping pad 2 and the roller 3, so that the final curved shape of the display panel P is completed. Afterwards, the upper pressing jig 4 and the shaping pad 2 each retract from the display panel P, the clamp 1 is released, and the roller 3 retracts, resulting in the final product.

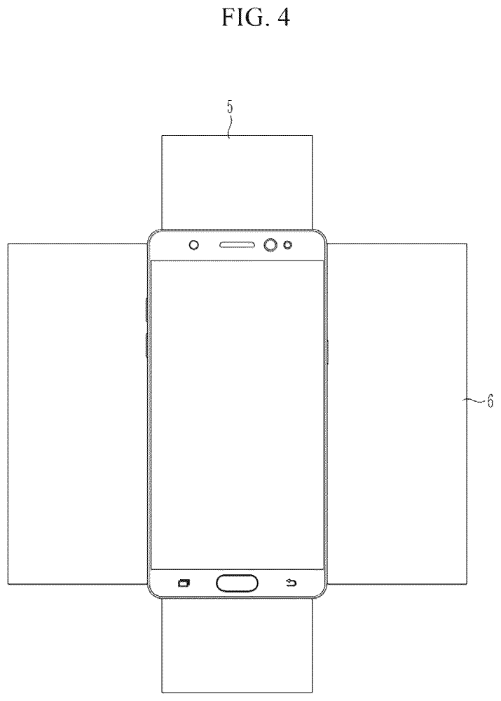

The above described method according to a comparative embodiment is suitable for a window laminating process of a flat display panel with a curved design of the conventional upper, lower, left, and right parts 5 and 6 shown in FIG. 4. However, the installation parts for the process are diverse and complicated, and the process is difficult with respect to the manufacture of display panel products with a circular three-dimensional design. In particular, during the manufacturing process, in the case of a circular three-dimensional display panel, defects such as cracks, shrinkage, and bubbles may occur in the edge area.

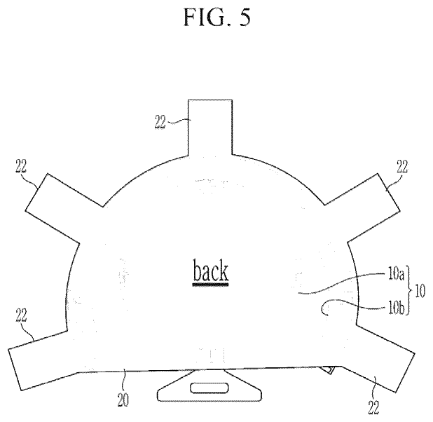

Hereinafter, a method of manufacturing a display panel according to an embodiment of the present disclosure will be described with reference to FIGS. 5 to 10.

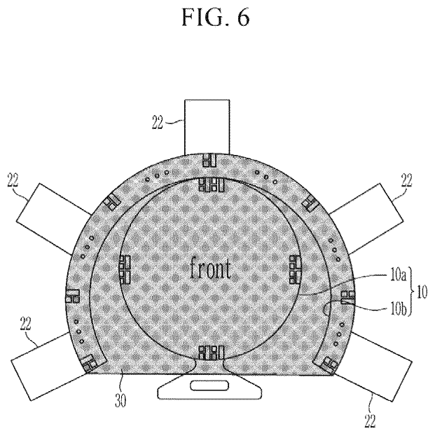

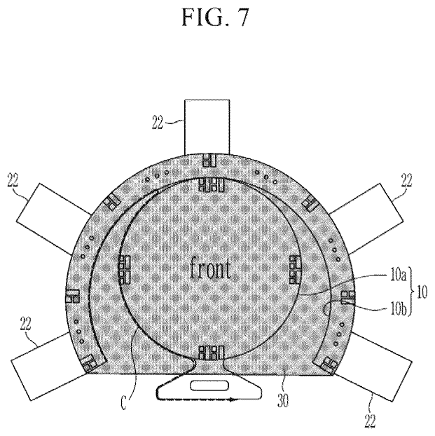

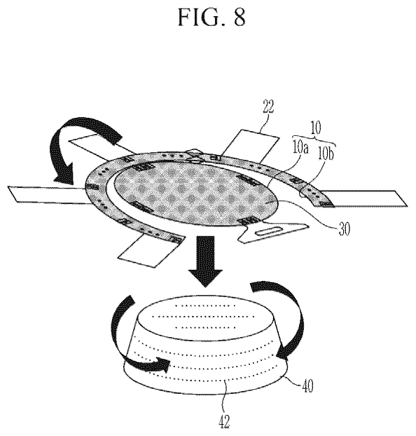

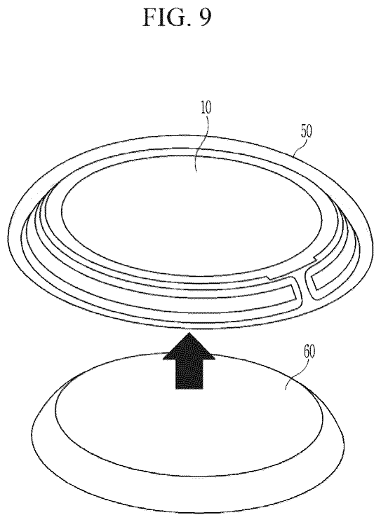

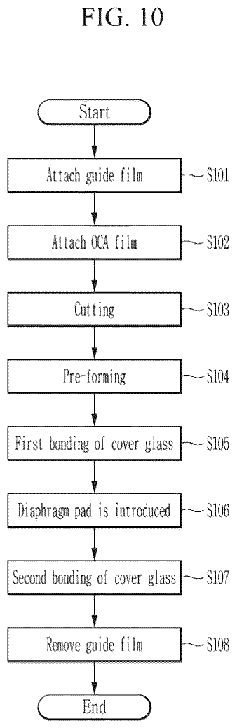

FIG. 5 illustrates a state in which a guide film is attached to a display panel in a method of manufacturing a display panel according to an embodiment of the present disclosure, FIG. 6 illustrates a state in which an OCA film is attached to a display panel in a method of manufacturing a display panel according to an embodiment of the present disclosure, FIG. 7 illustrates a cutting step in a method of manufacturing a display panel according to an embodiment of the present disclosure, FIG. 8 illustrates a pre-forming step in a method of manufacturing a display panel according to an embodiment of the present disclosure, FIG. 9 illustrates a state in which a diaphragm pad is introduced in a method of manufacturing a display panel according to an embodiment of the present disclosure, and FIG. 10 is a flowchart showing a method of manufacturing a display panel according to an embodiment of the present disclosure.

According to a method of manufacturing a display panel in an embodiment, as shown in FIG. 5, first, a guide film (G-film) 20 is attached to a side of the display panel 10 that forms the back surface of the display panel 10 in block S101 (FIG. 10).

The display panel 10 may be a flexible display panel. In an embodiment, the display panel 10 may include a main panel part 10a and a sub-panel part 10b arranged along the edge of the main panel part 10a. For example, the display panel 10 may include a flexible film and may be implemented by arranging an organic light emitting element and a pixel circuit on the flexible film. Flexible films may be formed of plastic materials such as polyimide, and may be bent or folded due to a property that allows easy bending by an external force.

In an embodiment, the guide film 20 is attached to the back surface of the display panel 10 through an adhesive. The guide film 20 may then be detached from the display panel 10 at a later stage of the process, after the shape of the display panel 10 has been modified. The guide film 20 may serve to increase the strength of the display panel 10 and prevent damage to the display panel 10 during the process. In an embodiment, the guide film 20 may be formed of a flexible plastic material.

A plurality of grippers 22 protruding to the outside of the sub-panel part 10b of the display panel 10 may be formed on the guide film 20. In an embodiment, the grippers 22 may be used to correct the position of the guide film 20 when attaching the guide film 20 to the display panel 10, and may be used as a handle when detaching the guide film 20 from the display panel 10. An embodiment shown in FIG. 5 includes five grippers 22 protruding to the outside of the sub-panel part 10b of the display panel 10 and symmetrically arranged. However, embodiments of the present disclosure are not necessarily limited thereto and the number of the plurality of grippers 22 and the arrangement thereof may vary. While each of the plurality of grippers 22 shown in an embodiment of FIG. 5 are rectangular shaped, embodiments of the present disclosure are not necessarily limited thereto and each of the grippers 22 may have various different shapes.

In an embodiment, as shown in FIG. 6, an OCA (Optical Clear Adhesive) film 30 is attached to a surface configuring the front surface of the display panel 10 in block S102 (FIG. 10) which is opposite to the surface configuring the back surface of the display panel 10.

In an embodiment, the OCA film 30 may include a substrate and an OCA release liner attached to the substrate through an adhesive. In an embodiment, the substrate may be a flexible film made of polyethylene terephthalate (PET) or polyethylene naphthalate (PEN).

In an embodiment, as shown in FIG. 7, the display panel 10, the guide film 20, and the OCA film 30 that are attached and integrated together are cut simultaneously in block S103 (FIG. 10).

In an embodiment, the attached display panel 10, guide film 20, and the OCA film 30 may be formed as partially cut planar elliptical or circular shape. For example, in an embodiment the attached display panel 10, the guide film 20, and the OCA film 30 may have an elliptical shape with the radius in the vertical direction smaller than the radius in the horizontal direction as shown in the drawing. In an embodiment, the bottom part may be cut in a straight line along the horizontal direction. This shape allows the edge portions to directly contact the side portions of the central portion to form a three-dimensional shape after the cutting step S103.

In the cutting step in block S103, the attached display panel 10, the guide film 20, and the OCA film 30 may be cut to have a central portion and an edge part disposed around (e.g., extending around) the central portion. The central portion may include the main panel part 10a, and the edge portion may include the sub-panel part 10b. In an embodiment, cutting is performed so that a cutting line C is formed along a portion of the edge of the central portion and a portion of the inner side of the edge portion. In an embodiment, the cutting line C may not extend to a top portion of the central portion and a top portion of the inner side of the edge portion. In an embodiment, the cutting may be performed by laser cutting or pressure cutting. In an embodiment as shown in FIG. 7, the upper part (e.g., the upper portion) may be in a form in which the central portion and the edge portion are attached, and the left, right, and lower sides may be in a form in which the central portion and the edge portion are separated (e.g., spaced apart from each other). For example, the central portion may be circular and the edge portion may be partially spaced apart from the central portion (e.g., on the left, right and lower sides) and partially connected to the central portion (e.g., on the upper portion).

In an embodiment, when the edge portion is folded towards the back side of the display panel 10, the edge portion is connected to the circumference of the central portion, so that the attached display panel 10, the guide film 20, and the OCA film 30 may form a three-dimensional shape.

In an embodiment, as shown in FIG. 8, the cut display panel 10, guide film 20, and OCA film 30 are disposed with the guide film 20 facing downward, and the shape stage 40 is advanced towards the guide film 20.

In an embodiment, the cut display panel 10, guide film 20, and OCA film 30 are pressed on the shape stage 40 to form a shape corresponding to the outer shape of the shape stage 40 (e.g., a pre-forming process) in block S104.

In an embodiment, the shape stage 40 has a greater hardness than the display panel 10 so that the shape of the display panel 10 is deformed into a three-dimensional shape by applying pressure thereon. If the pressure at this time is too great, there is a risk that the display panel 10 may be broken or damaged by the hardness of the shape stage 40, so the pressure applied to the display panel 10 may be adjusted to an appropriate intensity and speed to complete the pre-forming process without damaging the display panel 10.

In an embodiment, the shape stage 40 is formed in a shape corresponding to the shape in which the edge portion is folded towards the back side of the display panel 10. A plurality of vacuum holes 42 may be formed on the outer surface of the shape stage 40. In an embodiment, the plurality of vacuum holes 42 may be formed to be uniformly distributed along the central portion and the edge portion of the display panel 10.

In an embodiment, the plurality of vacuum holes 42 may be through holes that allow the central portion and the edge portion of the display panel 10 to be adsorbed to the outer surface of the shape stage 40 by negative pressure generated on the inner surface of the shape stage 40. Due to the presence of the vacuum holes 42, the display panel 10 seated on the shape stage 40 can be securely attached thereto.

Thereafter, a cover glass 50 is attached and pressed on the OCA film 30 to form the cover glass 50 into a shape corresponding to the outer shape of the shape stage 40 in block S105.

At this time, the OCA release liner is peeled from the substrate of the OCA film 30, and the cover glass 50 is bonded to the substrate. The bonding of the cover glass 50 to the OCA film 30 comprises a first bonding process. The pressure applied to the cover glass 50 may be adjusted to an appropriate intensity and speed so that the cover glass 50 is not broken or damaged by the hardness of the shape stage 40 during the performance of the first bonding process.

In an embodiment, as shown in FIG. 9, the shape stage 40 is removed by retracting from the guide film 20, and a diaphragm pad 60 is introduced at the position where the shape stage 40 was previously placed during the first bonding process in block S106. In an embodiment, the cover glass 50 is then pressed on the diaphragm pad 60 and formed into a shape corresponding to the outer shape of the diaphragm pad 60.

In an embodiment, the diaphragm pad 60 may be made of (e.g., composed of) soft silicone. The cover glass 50 and the display panel 10, which are first bonded and shaped on the shape stage 40, are secondarily bonded in block S107 in a second bonding process that is performed using a pressing force greater than that of the first bonding step (e.g., the first bonding process) in block S105. Since the diaphragm pad 60 is made of a soft material, the cover glass 50 and the display panel 10 are not cracked or damaged even when bonded using a pressing force greater than that of the first bonding step in block S105.

In an embodiment, the diaphragm pad 60 is then removed by retracting from the guide film 20, and the guide film 20 is removed in block S108. A plurality of grippers 22 formed on the guide film 20 can be gripped by an operator's hand or a tool to remove the guide film 20 from the display panel 10.

In an embodiment, after removal of the guide film 20, a protective layer may be further attached to the position where the diaphragm pad 60 was previously positioned during the second bonding process. In an embodiment, the protective layer may be made of a copper (Cu) panel for heat dissipation and providing exterior protection of the display panel 10.

As such, according to an embodiment of the present disclosure, by manufacturing a display panel that is completely bonded to a circular three-dimensional display panel, it is possible to prevent defects such as cracks, shrinkage, and bubbles from occurring in the edge area.

In addition, the method obviates a need for complicated and diverse machine parts such as clamps and rollers for the process, thereby reducing the possibility of malfunction and failure of equipment and increasing the productivity of the display panel window.

While the present disclosure has been described in connection with non-limiting embodiments, it should be understood that the present disclosure is not limited to the described embodiments, but, on the contrary, is intended to cover various modifications and equivalent arrangements included within the spirit and scope of the present disclosure.

What is claimed is:

1. A method of manufacturing a display device including a three-dimensional display panel, the method comprising:
attaching a guide film onto a back surface of the display panel;
attaching an OCA film onto a front surface of the display panel;
cutting the display panel, the guide film, and the OCA film that are attached to each other;
performing a pre-forming process by pressing the cut display panel, guide film, and OCA film onto a shape stage with the guide film facing downward, to form a shape of the cut display panel, guide film, and OCA film corresponding to an outer shape of the shape stage;
performing a first bonding process by attaching and pressing a cover glass onto the OCA film to form the cover glass into a shape corresponding to the outer shape of the shape stage;
removing the shape stage from the guide film and introducing a diaphragm pad into a position where the shape stage was previously placed during the first bonding process;
performing a second bonding process by pressing the cover glass onto the diaphragm pad to form a shape of the cover glass corresponding to the outer shape of the diaphragm pad; and
removing the diaphragm pad from the guide film and removing the guide film.

2. The method of claim 1, wherein the OCA film comprises a substrate and an OCA release liner attached to the substrate.

3. The method of claim 2, wherein the substrate is a film that comprises polyethylene terephthalate (PET) or polyethylene naphthalate (PEN).

4. The method of claim 2, wherein the performing of the first bonding process comprises peeling the OCA release liner from the substrate and bonding the cover glass to the substrate.

5. The method of claim 1, wherein:
the guide film includes a plurality of grippers protruding to an outside of the display panel.

6. The method of claim 5, wherein the plurality of grippers are symmetrically arranged around the display panel.

7. The method of claim 1, wherein:
the attached display panel, guide film, and OCA film have a partially cut planar elliptical or circular shape.

8. The method of claim 7, wherein:
the cutting comprises cutting the display panel, the guide film, and the OCA film that are attached to each other to have a central portion and an edge portion extending around the central portion.

9. The method of claim 8, wherein:
the central portion is circular; and
the edge portion is partially spaced apart from the central portion and partially connected to the central portion.

10. The method of claim 9, wherein:
the edge portion is folded towards a back side of the display panel, forming a shape where the edge portion is connected to the central portion.

11. The method of claim 10, wherein
the shape stage corresponds to a shape in which the edge portion is folded toward the back side of the display panel.

12. The method of claim 11, wherein
a plurality of vacuum holes are formed on an outer surface of the shape stage.

13. The method of claim 12, wherein
the plurality of vacuum holes are arranged to be uniformly distributed in the central portion and the edge portion.

14. The method of claim 13, wherein:
the plurality of vacuum holes comprise through holes that allow the central portion and the edge portion to be adsorbed to the outer surface of the shape stage by negative pressure generated on an inner surface of the shape stage.

15. The method of claim 1, further comprising
after the removing of the guide film, attaching a protective layer to a position where the diaphragm pad was previously placed during the second bonding process.

16. The method of claim 15, wherein
the protective layer is a copper panel that dissipates heat and provides exterior protection of the display panel.

17. The method of claim 1, wherein
the diaphragm pad is composed of soft silicone.

18. The method of claim 1, wherein
the performing of the second bonding process uses a pressing force greater than a pressing force of the first bonding process.
